(19) United States
(12) Patent Application Publication
(10) Pub. No.: US 2025/0365946 A1
(43) Pub. Date: Nov. 27, 2025

(54) MAGNETIC MEMORY DEVICE

(71) Applicant: Samsung Electronics Co., Ltd., Suwon-si (KR)

(72) Inventors: Kilho Lee, Suwon-si (KR); Daeshik Kim, Suwon-si (KR); Tadashi Kai, Suwon-si (KR)

(21) Appl. No.: 19/002,043

(22) Filed: Dec. 26, 2024

(30) Foreign Application Priority Data
May 21, 2024 (KR) 10-2024-0065862

(51) Int. Cl. H10B 20/25; H10B 61/00

(52) U.S. Cl. CPC H10B 20/25; H10B 61/10

(57) ABSTRACT

A magnetic memory device includes a first magnetic tunnel junction (MTJ) structure in the first region of a substrate, a second MTJ structure in the second region of the substrate, a first bit line electrically connected to the first MTJ structure, a second bit line electrically connected to the second MTJ structure, a first conductive structure between the substrate and the first MTJ structure and between the first MTJ structure and the first bit line, and a second conductive structure between the substrate and the second MTJ structure and between the second MTJ structure and the second bit line, the tunnel barrier layer of the second MTJ structure is configured to break down and the second MTJ structure is configured to transition to an irreversible state in response to application of a breakdown voltage to the second MTJ structure.

### CROSS-REFERENCE TO RELATED APPLICATION

This application and claims priority under 35 USC § 119 to Korean Patent Application No. 10-2024-0065862, filed on May 21, 2024, in the Korean Intellectual Property Office, the disclosure of which is incorporated by reference herein in its entirety.

### BACKGROUND

Embodiments of the inventive concept relate to magnetic memory devices, and more particularly, to a magnetic memory device including a magnetic tunnel junction (MTJ) structure.

As electronic products have become faster and consume less power, semiconductor devices embedded in electronic products have been required to have fast read/write operations and low operating voltages. In response to these demands, research has been actively conducted on magnetic memory devices that utilize the magnetoresistive properties of MTJ. In particular, highly integrated magnetic memory devices are capable of high-speed read and write operations and are non-volatile, so they are emerging as next-generation memory devices.

### SUMMARY

Some embodiments of the inventive concept provide a magnetic memory device including a normal memory cell array and a one-time programmable (OTP) memory cell array implemented on a single semiconductor chip and including an OTP memory cell capable of securing a relatively sufficient read operation margin.

However, the problems to be solved by the inventive concept are not limited to the problems mentioned above, and other problems may be clearly understood by those skilled in the art from the description below.

According to an aspect of the inventive concept, there is provided a magnetic memory device including a substrate including a first region and a second region adjacent to the first region, a first magnetic tunnel junction (MTJ) structure in the first region, a second MTJ structure in the second region, a first bit line electrically connected to the first MTJ structure, a second bit line electrically connected to the second MTJ structure, a first conductive structure between the substrate and the first MTJ structure and between the first MTJ structure and the first bit line, and a second conductive structure between the substrate and the second MTJ structure and between the second MTJ structure and the second bit line, wherein the second bit line, the second conductive structure, or both of the second bit line and second conductive structure include a ferromagnetic material, wherein the first MTJ structure and the second MTJ structure each include a pinned layer, a tunnel barrier layer, and a free layer, and wherein the tunnel barrier layer of the second MTJ structure is configured to break down and the second MTJ structure is configured to transition to an irreversible state in response to application of a breakdown voltage to the second MTJ structure.

According to another aspect of the inventive concept, there is provided a magnetic memory device including a substrate including a first region and a second region adjacent to the first region, a first magnetic tunnel junction (MTJ) in the first region, a second MTJ structure in the second region, a bit line and a selection transistor electrically connected to the first MTJ structure and the second MTJ structure, respectively, wherein the first MTJ structure and the second MTJ structure each include a pinned layer, a tunnel barrier layer, and a free layer, wherein an anti-parallel state of the second MTJ structure has greater energy stability than an anti-parallel state of the first MTJ structure, wherein a second energy barrier from the anti-parallel state to a parallel state of the second MTJ structure is larger in height than a first energy barrier from the anti-parallel state to a parallel state of the first MTJ structure, and wherein the tunnel barrier layer of the second MTJ structure is configured to break down and the second MTJ structure is configured to transition to an irreversible state in response to application of a breakdown voltage to the second MTJ structure.

According to another aspect of the inventive concept, there is provided a magnetic memory device including a substrate including a first region and a second region adjacent to the first region, a plurality of first memory elements constituting a normal memory cell in the first region, a plurality of second memory elements constituting one-time programmable (OTP) memory cells in the second region, a first bit line and a first selection transistor electrically connected to the plurality of first memory elements, and a second bit line and a second selection transistor electrically connected to the plurality of second memory elements, wherein the plurality of first memory elements and the plurality of second memory elements each include an MTJ structure including a pinned layer, a tunnel barrier layer, and a free layer which are sequentially stacked, a first conductive structure electrically connecting the first bit line to the MTJ structure and the MTJ structure to the first selection transistor in the first region, a second conductive structure electrically connecting the second bit line to the MTJ structure and the MTJ structure to the second selection transistor in the second region, wherein the first conductive structure and the second conductive structure each include an upper electrode in contact with an upper surface of the MTJ structure, a lower electrode in contact with a lower surface of the MTJ structure, a lower electrode contact spaced apart from the MTJ structure with the lower electrode therebetween, and a lower conductive line electrically connected to the lower electrode contact, wherein the first conductive structure and the first bit line include a diamagnetic material or a paramagnetic material, the lower conductive line, wherein the lower electrode contact, the lower electrode, the upper electrode, the second bit line, or combinations thereof constituting the second conductive structure include a ferromagnetic material, and wherein the tunnel barrier layer of the MTJ structure is configured to break down and the MTJ structure is configured to transition to an irreversible state in response to application of a breakdown voltage to the MTJ structure and some of the plurality of second memory elements.

### BRIEF DESCRIPTION OF THE DRAWINGS

Embodiments will be more clearly understood from the following detailed description taken in conjunction with the accompanying drawings in which:

FIG. 1 is a configuration diagram illustrating a magnetic memory device having a variable resistance element according to an embodiment;

FIG. 2 is a configuration diagram illustrating each memory cell included in a memory cell array of FIG. 1;

FIGS. 3A and 3B are conceptual diagrams illustrating data stored according to a magnetization direction in a magnetic tunnel junction (MTJ) structure of the memory cell of FIG. 2;

FIG. 4 is a conceptual diagram illustrating a magnetization direction according to a write operation in the MTJ structure of the memory cell of FIG. 2;

FIGS. 5A, 5B, 5C, 6, 7A, and 7B are conceptual diagrams illustrating different embodiments of the MTJ structure of the memory cell of FIG. 2;

FIG. 8 is a schematic plan view of a magnetic memory device according to an embodiment;

FIG. 9A is a graph illustrating a cell current of a one-time programmable (OTP) memory cell as a comparative example;

FIG. 9B is a graph illustrating a cell current of an OTP memory cell according to an embodiment;

FIG. 10A is a graph schematically illustrating an energy band diagram of a normal memory cell according to an embodiment;

FIG. 10B is a graph schematically illustrating an energy band diagram of an OTP memory cell according to an embodiment;

FIG. 11 is a cross-sectional view illustrating a normal memory cell structure of a magnetic memory device according to an embodiment;

FIG. 12 is a cross-sectional view illustrating an OTP memory cell structure of a magnetic memory device according to an embodiment;

FIG. 13 is a cross-sectional view illustrating an OTP memory cell structure of a magnetic memory device according to an embodiment;

FIG. 14 is a cross-sectional view illustrating an OTP memory cell structure of a magnetic memory device according to an embodiment;

FIG. 15 is a cross-sectional view illustrating an OTP memory cell structure of a magnetic memory device according to an embodiment;

FIG. 16 is a cross-sectional view illustrating an OTP memory cell structure of a magnetic memory device according to an embodiment;

FIG. 17 is a graph schematically illustrating an energy band diagram of an OTP memory cell according to an embodiment;

FIG. 18 is a cross-sectional view illustrating an OTP memory cell structure of a magnetic memory device according to an embodiment;

FIG. 19 is a schematic plan view of a magnetic memory device according to an embodiment;

FIG. 20A is a cross-sectional view illustrating a dummy memory cell structure of a magnetic memory device according to an embodiment;

FIG. 20B is a cross-sectional view illustrating a dummy memory cell structure of a magnetic memory device according to an embodiment;

FIG. 21 is a block diagram illustrating an electronic device including a magnetic memory device according to an embodiment; and

FIG. 22 is a block diagram illustrating a server system including a magnetic memory device according to an embodiment.

### DETAILED DESCRIPTION OF THE EMBODIMENTS

Hereinafter, embodiments are described in detail with reference to the accompanying drawings. The same reference numerals are used for the same components in the drawings, and redundant descriptions thereof are omitted.

In this specification, a horizontal direction may include a first horizontal direction (an X-direction and a second horizontal direction (a Y direction) that intersect each other. A direction intersecting the first horizontal direction (the X-direction) and the second horizontal direction (a Y-direction) may be referred to as a vertical direction (a Z-direction). In this specification, a vertical level may be referred to as a height level in the vertical direction (the Z-direction) of any configuration. As used herein, the term “and/or” includes any and all combinations of one or more of the associated listed items. It will be understood that when an element is referred to as being “on,” “attached” to, “connected” to, “coupled” with, “contacting,” etc., another element, it can be directly on, attached to, connected to, coupled with or contacting the other element or intervening elements may also be present. In contrast, when an element is referred to as being, for example, “directly on,” “directly attached” to, “directly connected” to, “directly coupled” with or “directly contacting” another element, there are no intervening elements present. It is noted that aspects described with respect to one embodiment may be incorporated in different embodiments although not specifically described relative thereto. That is, all embodiments and/or features of any embodiments can be combined in any way and/or combination.

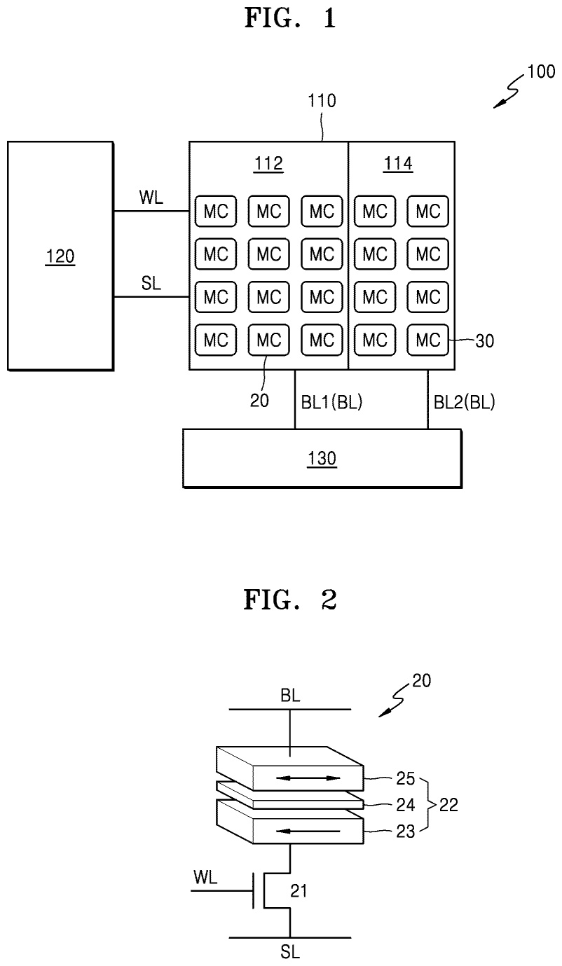

FIG. 1 is a configuration diagram illustrating a magnetic memory device 100 having a variable resistance element according to an embodiment.

Referring to FIG. 1, the magnetic memory device 100 may include a memory cell array 110, an address decoder circuit 120, and a data input/output (I/O) circuit 130.

The memory cell array 110 includes a plurality of memory cells MC arranged in rows and columns. The memory cells MC may include magnetic memory cells including variable resistance elements. For example, the magnetic memory device 100 may be magnetoresistive random access memory (MRAM) including an upper electrode of a magnetic material, a lower electrode of a magnetic material, and a dielectric therebetween.

In the magnetic memory device 100, each of the memory cells MC may include a selection transistor and a variable resistor implemented as a magnetic tunnel junction (MTJ). The memory cell array 110 includes a plurality of word lines WL, a plurality of bit lines BL, and a plurality of source lines SL electrically connected to the memory cells MC. Each of the word lines WL is electrically connected to a gate of the selection transistor of the memory cells MC located in one of the rows, and each of the bit lines BL and the source lines SL is electrically connected to the variable resistor of the memory cells MC located in one of the columns and a source of the selection transistor.

The memory cell array 110 includes a normal memory cell array 112 and a one-time programmable (OTP) memory cell array 114.

The normal memory cell array 112 includes a plurality of normal memory cells 20, and each of the normal memory cells 20 includes a first selection transistor and a first variable resistance element. The normal memory cell array 112 includes a first selection transistor electrically connected to each of the word lines WL respectively corresponding to the rows and a first variable resistor electrically connected to each of the bit lines BL respectively corresponding to the columns.

The OTP memory cell array 114 includes a plurality of OTP memory cells 30, and the OTP memory cells 30 include a second selection transistor and a second variable resistance element. The OTP memory cell 30 may have the same structure as the normal memory cell 20. The OTP memory cell array 114 may include a second selection transistor electrically connected to each of the word lines WL and a second variable resistance element connected to an OTP bit line (OBL) corresponding to one of the columns, and the second variable resistance element may be short-circuited. In some embodiments, the second variable resistance element of the OTP memory cell 30 may have an irreversible resistance state by applying a breakdown voltage (BV) in one programming operation to break down a tunnel barrier layer to have an irreversible resistance state.

The address decoder circuit 120 and the data I/O circuit 130 may be provided as peripheral circuits of the memory cell array 110.

The address decoder circuit 120 may be electrically connected to the memory cell array 110 through the word lines WL and the source lines SL. The address decoder circuit 120 may decode a row address to select the word lines WL and the source lines SL and decode a column address to select the bit lines BL.

The data I/O circuit 130 may be connected to the memory cell array 110 through the bit lines BL and the OBL. The data I/O circuit 130 may include a column selection circuit, a write driver circuit, and a sense amplifier circuit. The column selection circuit may select one of the bit lines BL in response to a column selection signal provided from the address decoder circuit 120, and a certain read/write voltage is applied to the bit line BL selected by the column selection circuit through the write driver circuit according to a read/write operation. In addition, the sense amplifier circuit determines data of the normal memory cell 20 in the normal memory cell array 112.

FIG. 2 is a configuration diagram illustrating each memory cell MC included in the memory cell array 110 of FIG. 1.

Referring to FIG. 2, the normal memory cell 20 is shown among the memory cells MC (see FIG. 1) included in the memory cell array 110 (see FIG. 1).

The normal memory cell 20 includes a selection transistor 21 and an MTJ structure 22. A gate of the selection transistor 21 may be electrically connected to the word line WL, and a drain electrode, one electrode of the selection transistor 21, may be electrically connected to the bit line BL through the MTJ structure 22. In addition, a source electrode, the other electrode of the selection transistor 21, may be electrically connected to the source line SL.

The MTJ structure 22 may include a pinned layer 23, a free layer 25, and a tunnel barrier layer 24 therebetween. A magnetization direction of the pinned layer 23 may be fixed, and a magnetization direction of the free layer 25 may be parallel (P) or anti-parallel (AP) to the magnetization direction of the pinned layer 23 depending on the data stored by a write operation. To fix the magnetization direction of the pinned layer 23, an anti-ferromagnetic layer may be further provided.

The pinned layer 23 may include a ferromagnetic material. For example, the pinned layer 23 may include at least one material selected from CoFeB, Fe, Co, Ni, Gd, Dy, CoFe, NiFe, MnAs, MnBi, MnSb, CrO, MnOFeO, FeOFeO, NiOFeO, CuOFeO, MgOFeO, EuO, and/or YFeO.

The tunnel barrier layer 24 may include a non-magnetic material. For example, the tunnel barrier layer 24 may include at least one material selected from magnesium (Mg), titanium (Ti), aluminum (Al), magnesium zinc oxide (MgZnO), titanium nitride (TiN), and/or vanadium nitride (VN).

The free layer 25 may include a ferromagnetic material including at least one of cobalt (Co), iron (Fe), and/or nickel (Ni). For example, the free layer 25 may include at least one material selected from FeB, Fe, Co, Ni, Gd, Dy, CoFe, NiFe, MnAs, MnBi, MnSb, CrO, MnOFeO, FeOFeO, NiOFeO, CuOFeO, MgOFeO, EuO, and/or YFeO.

In some embodiments, when the free layer 25 and the pinned layer 23 of the MTJ structure 22 are in the parallel (P) state, that is, when the MTJ structure 22 exhibits low resistance, the normal memory cell 20 is defined as a data 0 (zero) logic state. On the contrary, when the free layer 25 and the pinned layer 23 of the MTJ structure 22 are in the anti-parallel (AP) state, that is, when the MTJ structure 22 exhibits high resistance, the normal memory cell 20 is defined as a data 1 (one) logic state. In other embodiments, the normal memory cell 20 may be defined as the data 0 logic state in the anti-parallel (AP) state of the MTJ structure 22 and may be defined as the data 1 logic state in the parallel (P) state.

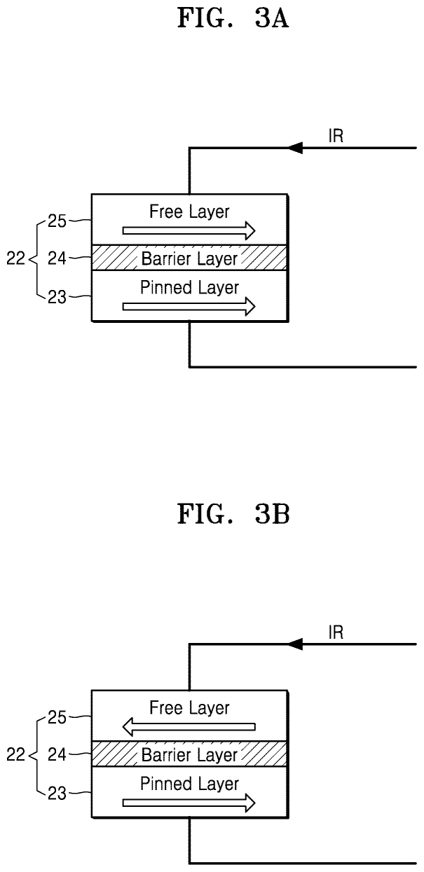

FIGS. 3A and 3B are conceptual diagrams illustrating data stored according to a magnetization direction in the MTJ structure 22 of the memory cell MC of FIG. 2.

Referring to FIGS. 3A and 3B, a resistance value of the MTJ structure 22 may vary depending on the magnetization direction of the free layer 25.

When a read current IR flows through the MTJ structure 22, a data voltage according to the resistance value of the MTJ structure 22 may be output. Because the intensity of the read current IR is much smaller than the intensity of a write current, the magnetization direction of the free layer 25 does not change due to the read current IR.

As shown in FIG. 3A, in the MTJ structure 22, the magnetization direction of the free layer 25 may be parallel to the magnetization direction of the pinned layer 23 (the free layer 25 and the pinned layer 23 are in the parallel (P) state). The MTJ structure 22 in this state may have a low resistance value, and data 0 may be output through a read operation.

As shown in FIG. 3B, in the MTJ structure 22, the magnetization direction of the free layer 25 may be anti-parallel to the magnetization direction of the pinned layer 23 (the free layer 25 and the pinned layer 23 are in the anti-parallel (AP) state). The MTJ structure 22 in this state may have a high resistance value, and data 1 may be output through a read operation.

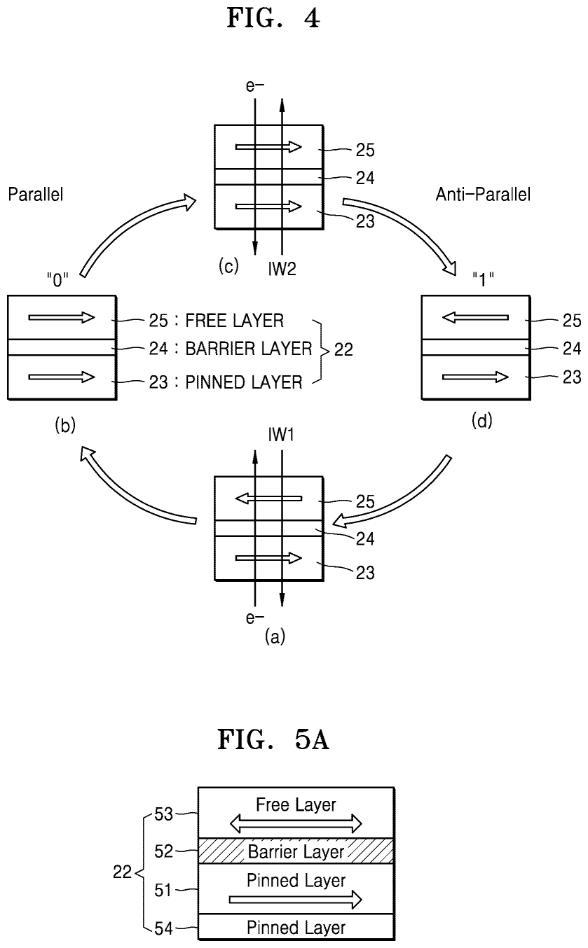

FIG. 4 is a conceptual diagram illustrating a magnetization direction according to a write operation in the MTJ structure of the memory cell of FIG. 2.

Referring to FIG. 4, the magnetization direction of the free layer 25 may be determined depending on the direction of first and second write currents IW1 and IW2 flowing through the MTJ structure 22.

When the first write current IW1 is applied from the free layer 25 to the pinned layer 23 as shown in (a), free electrons having the same spin direction as the pinned layer 23 apply torque to the free layer 25. Accordingly, the free layer 25 may be magnetized to be parallel to the pinned layer 23. Therefore, data 0 having a low resistance value may be stored in the MTJ structure 22 as shown in (b).

In addition, in the MTJ structure 22 in the data 0 state, when the second write current IW2 is applied from the pinned layer 23 to the free layer 25 as shown in (c), free electrons having a spin direction opposite to the pinned layer 3 return to the free layer 25 and apply torque to the free layer 25. Accordingly, the free layer 25 may be magnetized to be anti-parallel to the pinned layer 23. Therefore, data 1 having a high resistance value may be stored in the MTJ structure 22 as shown in (d).

That is, in the MTJ structure 22, the magnetization direction of the free layer 25 may be changed to be parallel or anti-parallel to the pinned layer 23 by spin transfer torque (STT), and accordingly, data 0 or data 1 may be stored in the MTJ structure 22.

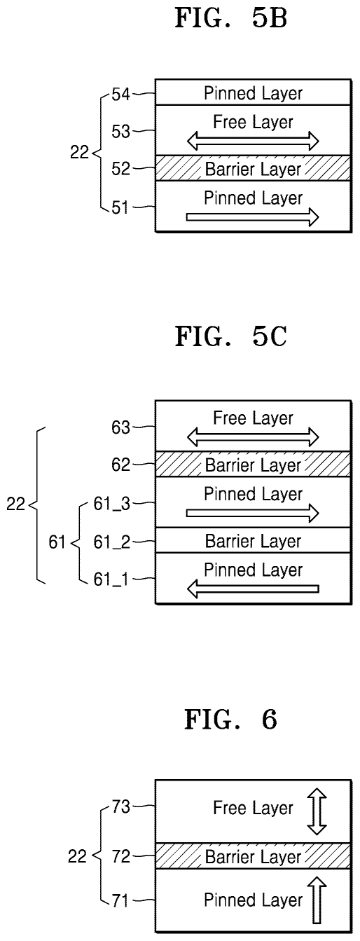

FIGS. 5A, 5B, 5C, 6, 7A, and 7B are conceptual diagrams illustrating different embodiments of the MTJ structure 22 of the memory cell MC of FIG. 2.

Referring to FIGS. 5A and 5B, the MTJ structure 22 may include a pinned layer 51, a tunnel barrier layer 52, a free layer 53, and an anti-ferromagnetic layer 54.

The anti-ferromagnetic layer 54 may include an anti-ferromagnetic material. For example, the anti-ferromagnetic layer 54 may include at least one material selected from PtMn, IrMn, MnO, MnS, MnTe, MnF, FeCl, FeO, CoCl, CoO, NiCl, NiO, and Cr.

Because the free layer 53 and the pinned layer 51 of the MTJ structure 22 are each formed of a ferromagnetic material, a stray magnetic field may be generated at the edge of the ferromagnetic material. The stray magnetic field may lower magnetic resistance or increase the magnetic resistance of the free layer 53. In particular, the stray magnetic field may affect switching characteristics to form asymmetric switching. Therefore, a structure that reduces or controls the stray magnetic field generated from the ferromagnetic material in the MTJ structure 22 may be needed.

Referring to FIG. 5C, the MTJ structure 22 may include a pinned layer 61, a tunnel barrier layer 62, and a free layer 63, and the pinned layer 61 may be provided as a synthetic anti-ferromagnetic material.

The pinned layer 61 may include a first ferromagnetic layer 61_1, a coupling layer 61_2, and a second ferromagnetic layer 61_3. For example, the first and second ferromagnetic layers 61_1 and 61_3 may each include at least one material selected from CoFeB, Fe, Co, Ni, Gd, Dy, CoFe, NiFe, MnAs, MnBi, MnSb, CrO, MnOFeO, FeOFeO, NiOFeO, CuOFeO, MgOFeO, EuO, and YFeO. For example, the coupling layer 61_2 may include ruthenium (Ru).

A magnetization direction of the first ferromagnetic layer 61_1 may be different from a magnetization direction of the second ferromagnetic layer 61_3, and each magnetization direction may be fixed.

Referring to FIG. 6, a magnetization direction of the MTJ structure 22 is perpendicular to a tunnel barrier layer 72, and accordingly, a movement direction of current may be substantially parallel to a magnetization easy axis.

A structure in which the magnetization direction is perpendicular is called a vertical MTJ structure. The vertical MTJ structure 22 also includes a pinned layer 71, the tunnel barrier layer 72, and a free layer 73. When a magnetization direction of the free layer 73 is parallel to a magnetization direction of the pinned layer 71, a resistance value may decrease, and when the magnetization direction of the free layer 73 is anti-parallel to the magnetization direction of the pinned layer 71, the resistance value may increase. Therefore, data may be stored in the vertical MTJ structure 22 depending on the resistance value.

To implement the vertical MTJ structure 22, the free layer 73 and the pinned layer 71 may include a material having high magnetic anisotropy energy. For example, each of the free layer 73 and the pinned layer 71 may be an ordered alloy and may include at least one material selected from iron (Fe), cobalt (Co), nickel (Ni), palladium (Pa), and/or platinum (Pt). In addition, each of the free layer 73 and the pinned layer 71 may include at least one material selected from an Fe—Pt alloy, an Fe—Pd alloy, a Co—Pd alloy, a Co—Pt alloy, an Fe—Ni—Pt alloy, a Co—Fe—Pt alloy, and/or a Co—Ni—Pt alloy.

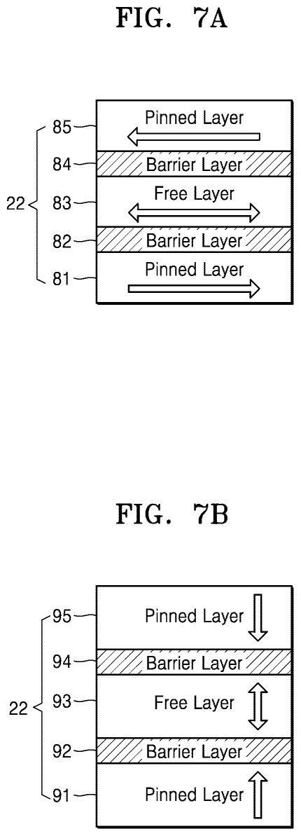

Referring to FIG. 7A, a dual MTJ structure 22 is shown in which first and second tunnel barrier layers 82 and 84 and first and second pinned layers 81 and 85 are respectively arranged at both ends based on a free layer 83.

The dual MTJ structure 22 forming horizontal magnetism may include the first pinned layer 81, the first tunnel barrier layer 82, the free layer 83, the second tunnel barrier layer 84, and the second pinned layer 85. The first and second pinned layers 81 and 85 may be similar to the pinned layer 51 (see FIG. 5A), the first and second tunnel barrier layers 82 and 84 may be similar to the tunnel barrier layer 52 (see FIG. 5A), and the free layer 83 may be similar to the free layer 53 (see FIG. 5A).

When a magnetization direction of the first pinned layer 81 and a magnetization direction of the second pinned layer 85 are fixed in opposite directions, an effect of substantially canceling out magnetic force caused by the first and second pinned layers 81 and 85 may be achieved. The dual MTJ structure 22 may perform a read operation using less current than a general MTJ device. The dual MTJ structure 22 provides higher resistance than a general MTJ device during a read operation due to the second tunnel barrier layer 84, so a clear resistance value may be obtained.

Referring to FIG. 7B, a vertical dual MTJ structure 22 is shown in which first and second tunnel barrier layers 92 and 94 and first and second pinned layers 91 and 95 are respectively disposed at both ends based on a free layer 93.

The vertical dual MTJ structure 22 forming vertical magnetism may include the first pinned layer 91, the first tunnel barrier layer 92, the free layer 93, the second tunnel barrier layer 94, and the second pinned layer 95. The first and second pinned layers 91 and 95 may be similar to the pinned layer 71 (see FIG. 6), the first and second tunnel barrier layers 92 and 94 may be similar to the tunnel barrier layer 72 (see FIG. 6), and the free layer 93 may be similar to the free layer 73 (see FIG. 6).

When a magnetization direction of the first pinned layer 91 and a magnetization direction of the second pinned layer 95 are fixed in opposite directions, an effect of substantially canceling out magnetic force caused by the first and second pinned layers 81 and 85 may be achieved. The vertical dual MTJ structure 22 may perform a read operation using less current than a general MTJ device. The vertical dual MTJ structure 22 may provide higher resistance during a read operation due to the second tunnel barrier layer 94, so a clear resistance value may be obtained.

The MTJ structure of the normal memory cell 20 (see FIG. 1) described above with reference to FIGS. 3A to 7B may also be applied substantially equally to the OTP memory cell 30 (see FIG. 1) of the OTP memory cell array 114 (see FIG. 1).

In some embodiments, the MTJ structure of the OTP memory cell 30 may be a resistance element that serves as a reference for determining data of the normal memory cell 20. Therefore, to more stably determine data of the normal memory cell 20, the MTJ structure of the OTP memory cell 30 may be required to have a constant resistance value.

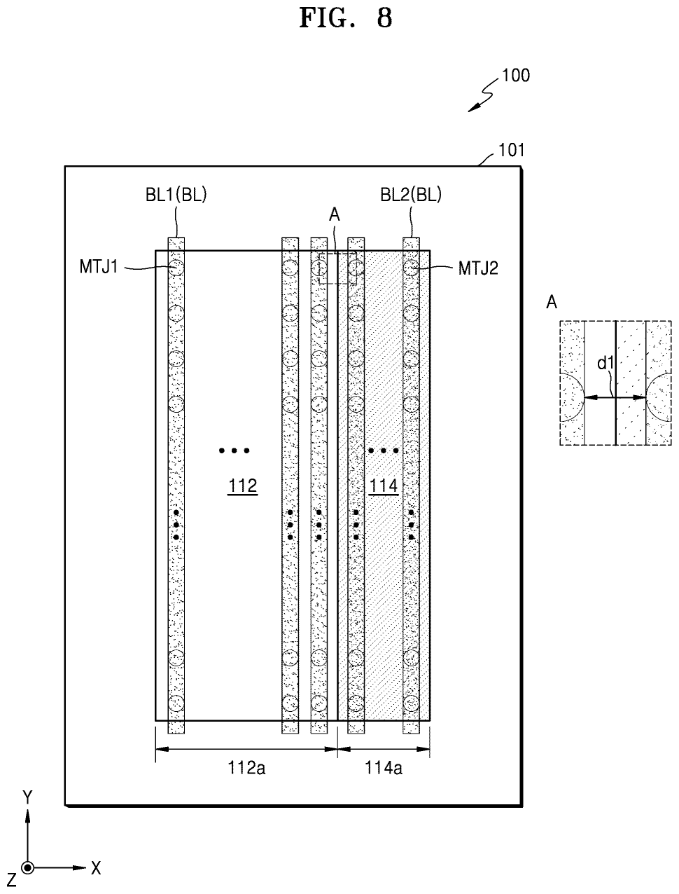

FIG. 8 is a schematic plan view of a magnetic memory device 100 according to an embodiment.

Referring to FIG. 8, the magnetic memory device 100 may include a substrate 101, and the substrate 101 may include a first region 112a in which a normal memory cell array 112 including a plurality of normal memory cells is located and a second region 114a in which an OTP memory cell array 114 including a plurality of OTP memory cells is located. In embodiments, the first region 112a may be adjacent to the second region 114a. In other embodiments, the first region 112a may be spaced apart from the second region 114a.

Here, the normal memory cells of the normal memory cell array 112 may each be programmed a plurality of times, while the OTP memory cells of the OTP memory cell array 114 may each be programmed only once. The magnetic memory device 100 may use an MRAM device and an OTP device simultaneously.

A first MTJ structure MTJ1 constituting a normal memory cell may be in the first region 112a. A plurality of first MTJ structures MTJ1 may be arranged to be spaced apart from each other in the first horizontal direction (the X-direction) and the second horizontal direction (the Y-direction), and a plurality of first bit lines BL1 may be disposed on the first MTJ structures MTJ1 to overlap the first MTJ structures MTJ1 in the vertical direction (the Z-direction). The first bit lines BL1 may be arranged to be spaced apart from each other in the first horizontal direction (the X-direction) and may extend in the second horizontal direction (the Y-direction).

A second MTJ structure MTJ2 constituting an OTP memory cell may be disposed in the second region 114a. A plurality of second MTJ structures MTJ2 may be arranged to be spaced apart from each other in the first horizontal direction (X-direction) and the second horizontal direction (the Y-direction), and a plurality of second bit lines BL2 may be arranged on the second MTJ structures MTJ2 to overlap the second MTJ structures MTJ2 in the vertical direction (the Z direction). The second bit lines BL2 may be arranged to be spaced apart from each other in the first horizontal direction (the X-direction) and may extend in the second horizontal direction (the Y-direction).

The minimum distance dl between the first MTJ structure MTJ1 in the first region 112a and the second MTJ structure MTJ2 on the adjacent second region 114a may be within 110 nanometers to 160 nanometers or may be within 130 nanometers to 140 nanometers.

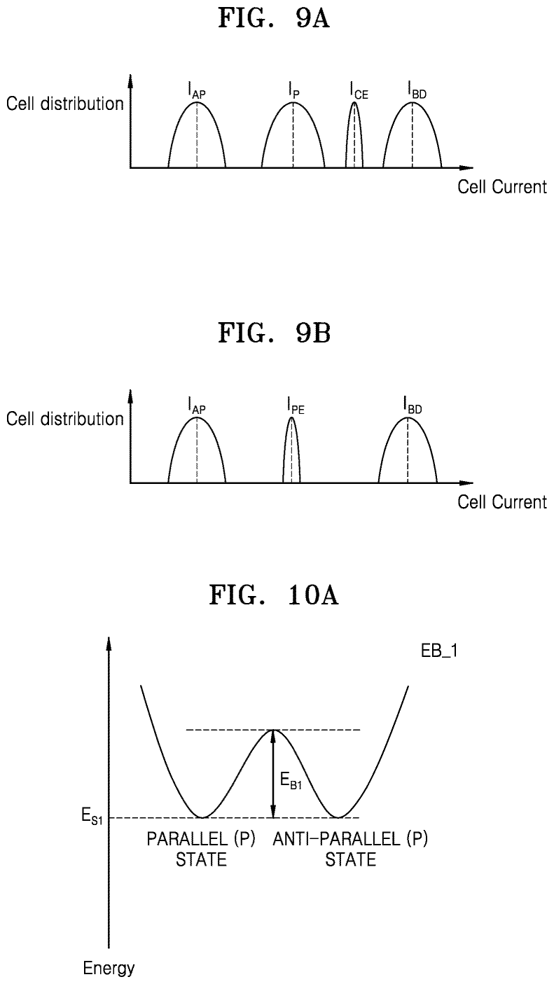

FIG. 9A is a graph illustrating cell current of an OTP memory cell as a comparative example.

FIG. 9B is a graph illustrating cell current of an OTP memory cell according to an embodiment.

Referring to FIGS. 9A and 9B, in the OTP memory cell as a comparative example, there are a cell current I_{AP} in an anti-parallel (AP) state and a cell current I_{P} and a breakdown current I_{BD} in a parallel (P) state, and for a read operation to be performed, a cell current I_{CE} having a value between the cell current I_{AP} in the anti-parallel (AP) state and the cell current I_{P} and the breakdown current I_{BD} in the parallel (P) state, is required. In comparison, in the OTP memory cell according to an embodiment, there are a cell current I_{AP} and a breakdown current I_{BD} in the anti-parallel (AP) state, and for a read operation to be performed, a cell current I_{PE} having a value between the cell current I_{AP} and the breakdown current I_{BD} in the anti-parallel (AP) state is required, so a relatively sufficient margin for the read operation may be secured. In other words, while most OTP memory cells exist in the anti-parallel (AP) state, there are relatively few OTP memory cells existing in the parallel (P) state, so a relatively sufficient margin for the read operation may be secured by the OTP memory cells in a breakdown state with a relatively significant resistance difference and the OTP memory cell in the anti-parallel (AP) state.

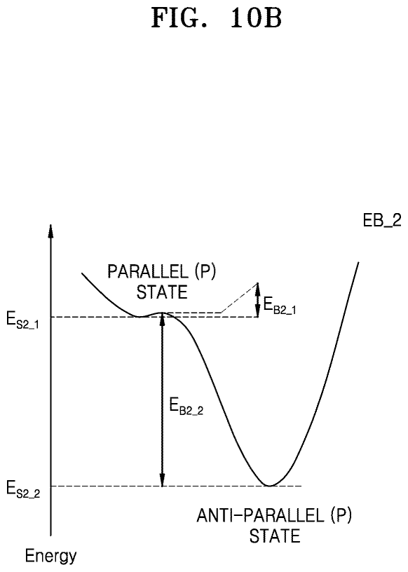

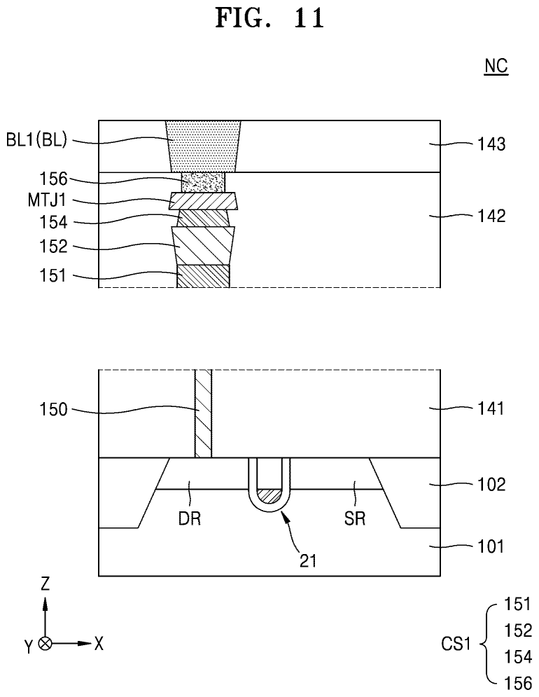

FIG. 10A is a graph schematically illustrating an energy band diagram EB_1 of a normal memory cell according to an embodiment.

FIG. 10B is a graph schematically illustrating an energy band diagram EB_2 of an OTP memory cell according to an embodiment.

Referring to FIG. 10A, the energies in the parallel (P) state and the anti-parallel (AP) state of the OTP memory cell as a comparative example are each E_{S1}, which is ideally equal, and any one state selected from the parallel (P) state and the anti-parallel (AP) state is not energetically preferred over the other in terms of energy. For a transition from the parallel (P) state to the anti-parallel (AP) state or from the anti-parallel (AP) state to the parallel (P) state, the energy barrier of E_{B1} has to be overcome.

Referring to FIG. 10B, the energies of the parallel (P) state and anti-parallel (AP) state of the OTP memory cell of embodiments of the inventive concept are E_{S2_1} and E_{S2_2}, respectively, and the energy in the anti-parallel (AP) state is lower than that of the parallel (P) state, and thus, the anti-parallel (AP) state may be more preferred to the parallel (P) state in terms of energy. For a transition from the parallel (P) state to the anti-parallel (AP) state, the energy barrier of E_{B2_1} has to be overcome, and for a transition from the anti-parallel (AP) state to the parallel (P) state, the energy barrier of E_{B2_2} has to be overcome. Because the energy barrier of E_{B2_1} is lower than that of E_{B2_2}, the transition from the parallel (P) state to the anti-parallel (AP) state is relatively preferred to the transition from the anti-parallel (AP) state to the parallel (P) state in terms of energy. Therefore, it may be assumed that the OTP memory cell of embodiments of the inventive concept will exist in the anti-parallel (AP) state rather than in the parallel (P) state.

FIG. 11 is a cross-sectional view illustrating a normal memory cell structure NC of a magnetic memory device according to an embodiment.

Referring to FIG. 11, the first MTJ structure MTJ1 in the first region 112a (see FIG. 11) may be electrically connected to a drain region DR of the selection transistor 21 located below the first MTJ structure MTJ1 sequentially through a lower electrode 154, a lower electrode contact 152, a lower conductive line 151, and a contact 150 and may be electrically connected to a first bit line BL1 located above the first MTJ structure MTJ1 through an upper electrode 156.

A first conductive structure CS1 may include conductive components located between the substrate 101 and the first MTJ structure MTJ1 and between the first MTJ structure MTJ1 and the first bit line BL1 in the first region 112a. In embodiments, the lower conductive line 151, the lower electrode contact 152, the lower electrode 154, and the upper electrode 156 may be included in the first conductive structure CS1.

The substrate 101 may include a semiconductor material, for example, a group IV semiconductor, a group III-V compound semiconductor, or a group II-VI oxide semiconductor. For example, the group IV semiconductor may include silicon (Si), germanium (Ge), or silicon-germanium. The substrate 101 may be provided as a bulk wafer or a wafer on which an epitaxial layer is formed. In other embodiments, the substrate 101 may include a silicon on insulator (SOI) substrate or a germanium on insulator (GeOI) substrate.

A device isolation film 102 and an active region defined by the device isolation film 102 may be defined within the substrate 101. The device isolation film 102 may include silicon oxide, silicon nitride, or combinations thereof. For example, the selection transistor 21 may be disposed in the active region of the substrate 101. The selection transistor 21 may include, for example, a buried gate-type selection transistor but is not limited thereto. The selection transistor 21 electrically connected to the first MTJ structure MTJ1 may be referred to as a “first selection transistor.”

A source region SR and the drain region DR may be formed on both sides of the selection transistor 21. The drain region DR of the selection transistor 21 may be electrically connected to the lower conductive line 151 through the contact 150 passing through the first insulating layer 141 and may be electrically connected to the lower electrode contact 152 through the lower conductive line 151. The lower electrode 154 may be disposed on the lower electrode contact 152, and the first MTJ structure MTJ1 may be disposed on the lower electrode 154. The upper electrode 156 may be disposed on the first MTJ structure MTJ1, and a bit line BL may be electrically connected to the first MTJ structure MTJ1 through the upper electrode 156.

In some embodiments, the contact 150 may be located within the first insulating layer 141, and the lower electrode contact 152, the lower electrode 154, the first MTJ structure MTJ1, and the upper electrode 156 may be located within a second insulating layer 142. In addition, the first bit line BL1 may be disposed within a third insulating layer 143.

In some embodiments, the first insulating layer 141, the second insulating layer 142, and the third insulating layer 143 may each be formed as a single-layer structure or a multi-layer structure. For example, the first insulating layer 141, the second insulating layer 142, and the third insulating layer 143 may each include an oxide film, a nitride film, and an ultra-low k (ULK) film having an ultra-low dielectric constant K of about 2.2 to about 2.4, or combinations thereof. For example, the first insulating layer 141, the second insulating layer 142, and the third insulating layer 143 may each include a tetraethylorthosilicate (TEOS) film, a high density plasma (HDP) oxide film, a boro-phospho-silicate glass (BPSG) film, a flowable chemical vapor deposition (FCVD) oxide film, a SiON film, a SiN film, a SiOC film, a SiCOH film, or combinations thereof but embodiments are not limited thereto.

The lower conductive line 151, the lower electrode contact 152, the lower electrode 154, the upper electrode 156, and the first bit line BL1 may each include a conductive material and may include a non-magnetic or paramagnetic material not sensitive to a magnetic field. In some embodiments, the lower conductive line 151, the lower electrode contact 152, the lower electrode 154, the upper electrode 156, and the first bit line BL1 may each include molybdenum (Mo), copper (Cu), tungsten (W), cobalt (Co), ruthenium (Ru), manganese (Mn), titanium (Ti), tantalum (Ta), aluminum (Al), combinations thereof, alloys thereof, or metal nitride but embodiments are not limited thereto.

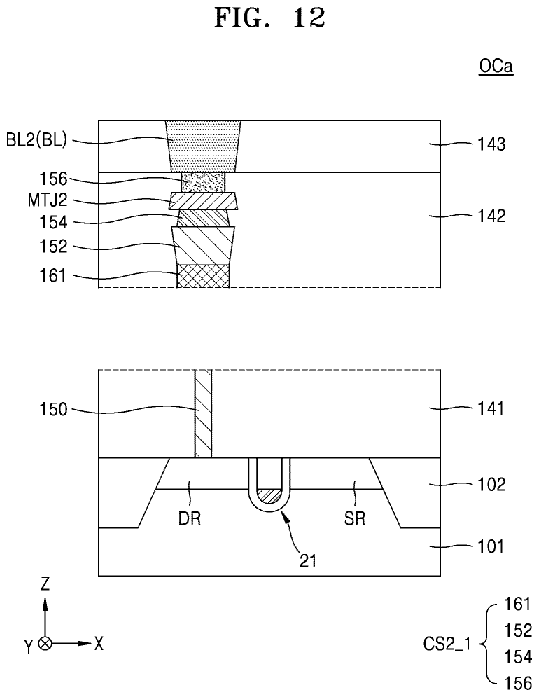

FIG. 12 is a cross-sectional view illustrating an OTP memory cell structure OCa of a magnetic memory device according to an embodiment. Unlike the normal memory cell structure NC of FIG. 11 including the lower conductive line 151, the OTP memory cell structure OCa of FIG. 12 may be configured to be substantially similar to the normal memory cell structure NC, except that the OTP memory cell structure OCa includes a ferromagnetic lower conductive line 161, so the differences from the normal memory cell structure NC are described in detail below.

Referring to FIG. 12, the second MTJ structure MTJ2 in the second region 114a (see FIG. 11) may be electrically connected to the drain region DR of the selection transistor 21 located below the second MTJ structure MTJ2 sequentially through the lower electrode 154, the lower electrode contact 152, the ferromagnetic lower conductive line 161, and the contact 150 and may be electrically connected to a second bit line BL2 disposed above the second MTJ structure MTJ2 through the upper electrode 156. The selection transistor 21 electrically connected to the second MTJ structure MTJ2 may be referred to as a “second selection transistor.”

The term “second conductive structure” used in this specification may include conductive components located between the substrate 101 and the second MTJ structure MTJ2 and between the second MTJ structure MTJ2 and the second bit line BL2. In embodiments, the second conductive structure CS2_1 may include the ferromagnetic lower conductive line 161, the lower electrode contact 152, the lower electrode 154, and the upper electrode 156. In some embodiments, the ferromagnetic lower conductive line 161 may be located within the second insulating layer 142.

The ferromagnetic lower conductive line 161 may include a ferromagnetic material. For example, the ferromagnetic lower conductive line 161 may include at least one material selected from iron (Fe), cobalt (Co), nickel (Ni), gadolinium (Gd), dynamium diode (Dy), CoFeB, CoFe, NiFe, MnAs, MnBi, MnSb, CrO, MnOFeO, FeOFeO, NiOFeO, CuOFeO, MgOFeO, EuO, and/or YFeO.

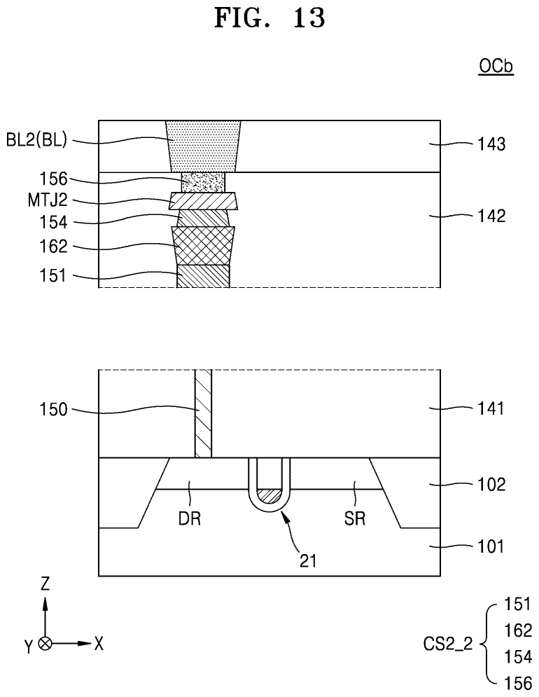

FIG. 13 is a cross-sectional view illustrating an OTP memory cell structure OCb of a magnetic memory device according to an embodiment. Unlike the normal memory cell structure NC of FIG. 11 including the lower electrode contact 152, the OTP memory cell structure OCb of FIG. 13 may be configured to be substantially similar to the normal memory cell structure NC, except that the OTP memory cell structure OCb includes a ferromagnetic lower electrode contact 162, so the differences from the normal memory cell structure NC are described in detail below.

Referring to FIG. 13, the second MTJ structure MTJ2 included in the OTP memory cell 30 (see FIG. 1) of the OTP memory cell array 114 (see FIG. 1) is shown. The second MTJ structure MTJ2 may be electrically connected to the drain region DR of the selection transistor 21 located below the second MTJ structure MTJ2 sequentially through the lower electrode 154, the ferromagnetic lower electrode contact 162, the lower conductive line 151, and the contact 150 and may be electrically connected to the second bit line BL2 located above the second MTJ structure MTJ2 through the upper electrode 156.

In embodiments, a second conductive structure CS2_2 may include the lower conductive line 151, the ferromagnetic lower electrode contact 162, the lower electrode 154, and the upper electrode 156. In some embodiments, the ferromagnetic lower electrode contact 162 may be located within second insulating layer 142.

The ferromagnetic lower electrode contact 162 may include a ferromagnetic material. For example, the ferromagnetic lower electrode contact 162 may include at least one material selected from iron (Fe), cobalt (Co), nickel (Ni), gadolinium (Gd), dynamium diode (Dy), CoFeB, CoFe, NiFe, MnAs, MnBi, MnSb, CrO, MnOFeO, FeOFeO, NiOFeO, CuOFeO, MgOFeO, EuO, and YFeO.

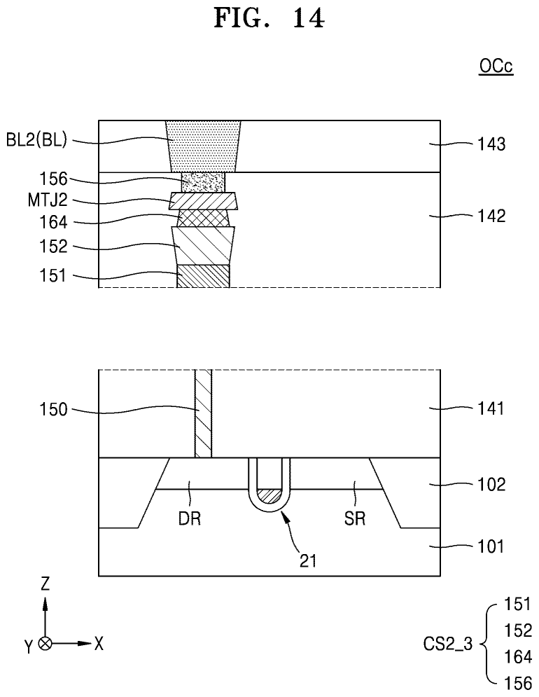

FIG. 14 is a cross-sectional view illustrating an OTP memory cell structure OCc of a magnetic memory device according to an embodiment. Unlike the normal memory cell structure NC of FIG. 11 including the lower electrode 154, the OTP memory cell structure OCc of FIG. 14 may be configured to be substantially similar to the normal memory cell structure NC, except that the OTP memory cell structure OCc includes a ferromagnetic lower electrode 164, so the differences from the normal memory cell structure NC are described in detail below.

Referring to FIG. 14, the second MTJ structure MTJ2 included in the OTP memory cell 30 (see FIG. 1) of the OTP memory cell array 114 (see FIG. 1) is shown. The second MTJ structure MTJ2 may be electrically connected to the drain region DR of the selection transistor 21 located below the second MTJ structure MTJ2 sequentially through the ferromagnetic lower electrode 164, the lower electrode contact 152, the lower conductive line 151, and the contact 150 and may be electrically connected to the second bit line BL2 located above the second MTJ structure MTJ2 through the upper electrode 156.

In embodiments, a second conductive structure CS2_3 may include the lower conductive line 151, the lower electrode contact 152, the ferromagnetic lower electrode 164, and the upper electrode 156. In some embodiments, the ferromagnetic lower electrode 164 may be located within the second insulating layer 142.

The ferromagnetic lower electrode 164 may include a ferromagnetic material. For example, the ferromagnetic lower electrode 164 may include at least one material selected from iron (Fe), cobalt (Co), nickel (Ni), gadolinium (Gd), dynamium diode (Dy), CoFeB, CoFe, NiFe, MnAs, MnBi, MnSb, CrO, MnOFeO, FeOFeO, NiOFeO, CuOFeO, MgOFeO, EuO, and/or YFeO.

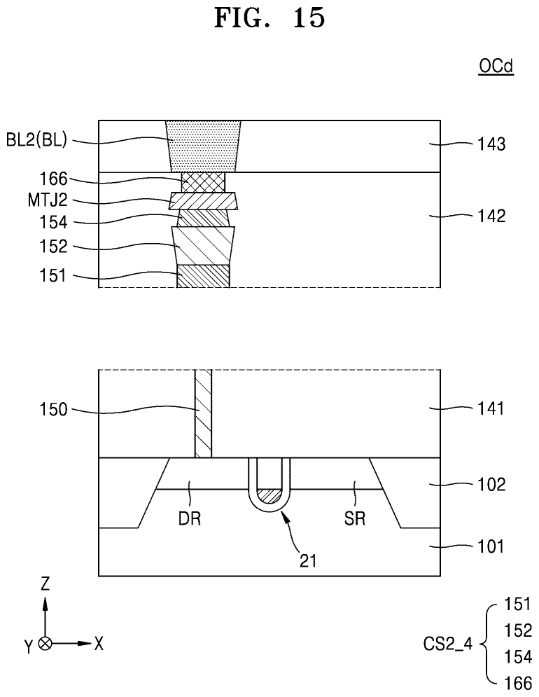

FIG. 15 is a cross-sectional view illustrating an OTP memory cell structure OCd of a magnetic memory device according to an embodiment. Unlike the normal memory cell structure NC of FIG. 11 including the upper electrode 156, the OTP memory cell structure OCd of FIG. 15 may be configured to be substantially similar to the normal memory cell structure NC, except that the OTP memory cell structure OCd includes a ferromagnetic upper electrode 166, so the differences from the normal memory cell structure NC are described in detail below.

Referring to FIG. 15, the second MTJ structure MTJ2 included in the OTP memory cell 30 (see FIG. 1) of the OTP memory cell array 114 (see FIG. 1) is shown. The second MTJ structure MTJ2 may be electrically connected to the drain region DR of the selection transistor 21 located below the second MTJ structure MTJ2 sequentially through the lower electrode 154, the lower electrode contact 152, the ferromagnetic lower conductive line 161, and the contact 150 and may be electrically connected to the second bit line BL2 located above the second MTJ structure MTJ2 through the ferromagnetic upper electrode 166.

In embodiments, a second conductive structure CS2_4 may include the lower conductive line 151, the lower electrode contact 152, the lower electrode 154, and the ferromagnetic upper electrode 166. In some embodiments, the ferromagnetic upper electrode 166 may be located within the second insulating layer 142.

The ferromagnetic upper electrode 166 may include a ferromagnetic material. For example, the ferromagnetic lower electrode 164 may include at least one material selected from iron (Fe), cobalt (Co), nickel (Ni), gadolinium (Gd), dynamium diode (Dy), CoFeB, CoFe, NiFe, MnAs, MnBi, MnSb, CrO, MnOFeO, FeOFeO, NiOFeO, CuOFeO, MgOFeO, EuO, and/or YFeO.

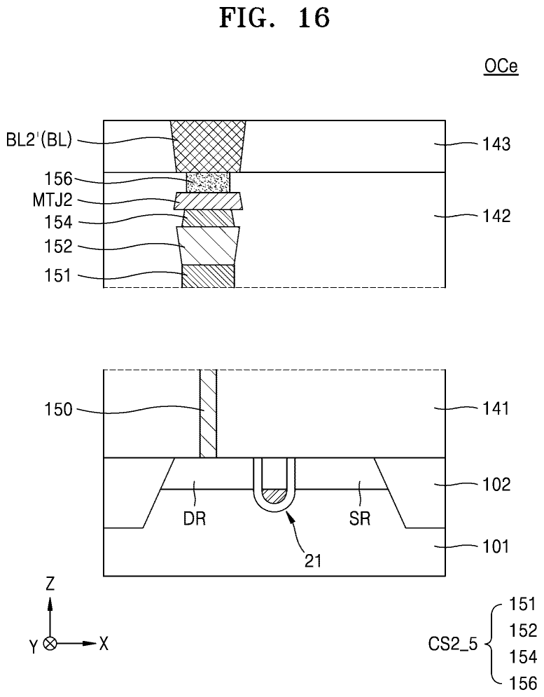

FIG. 16 is a cross-sectional view illustrating an OTP memory cell structure OCe of a magnetic memory device according to an embodiment. The OTP memory cell structure OCe of FIG. 16 may be configured to be substantially similar to the normal memory cell structure NC of FIG. 11 except that the OTP memory cell structure OCe includes a second bit line BL2′, so the differences from the normal memory cell structure NC are described in detail below.

Referring to FIG. 16, the second MTJ structure MTJ2 included in the OTP memory cell 30 (see FIG. 1) of the OTP memory cell array 114 (see FIG. 1) is shown. The second MTJ structure MTJ2 may be electrically connected to the drain region DR of the selection transistor 21 located below the second MTJ structure MTJ2 sequentially through the lower electrode 154, the lower electrode contact 152, the lower conductive line 151, and the contact 150 and may be electrically connected to the second bit line BL2′ located above the second MTJ structure MTJ2 through the upper electrode 156. The second bit line BL2′ may be disposed within the third insulating layer 143.

In embodiments, a second conductive structure CS2_5 may include the lower conductive line 151, the lower electrode contact 152, the lower electrode 154, and the upper electrode 156.

Compared to the second bit line BL2 (see FIGS. 12 to 15) of FIGS. 12 to 15 including a non-magnetic material or a paramagnetic material, the second bit line BL2′ may include a ferromagnetic material. For example, the second bit line BL2′ may include at least one material selected from iron (Fe), cobalt (Co), nickel (Ni), gadolinium (Gd), dynamium diode (Dy), CoFeB, CoFe, NiFe, MnAs, MnBi, MnSb, CrO, MnOFeO, FeOFeO, NiOFeO, CuOFeO, MgOFeO, EuO, and/or YFeO.

Each of the embodiments described above with reference to FIGS. 12 to 16 may be combined with each other. The magnetic memory device of the inventive concept may include at least one of the ferromagnetic lower conductive line 161, the ferromagnetic lower electrode contact 162, the ferromagnetic lower electrode 164, the ferromagnetic upper electrode 166, and the second bit line BL2′. The ferromagnetic lower conductive line 161, the ferromagnetic lower electrode contact 162, the ferromagnetic lower electrode 164, the ferromagnetic upper electrode 166, and the second bit line BL2′ may each form, for example, a stray magnetic field.

In the second MTJ structure MTJ2, the energy of the anti-parallel (AP) state is lower than that of the parallel (P) state due to the influence of the stray magnetic field formed by the ferromagnetic lower conductive line 161, the ferromagnetic lower electrode contact 162, the ferromagnetic lower electrode 164, the ferromagnetic upper electrode 166, and the second bit line BL2′, so the anti-parallel (AP) state is preferred to the parallel (P) state in terms of energy, and thus, the likelihood of a transition from the anti-parallel (AP) state to the parallel (P) state may be reduced, OTP cells existing in the parallel (P) state may be minimized or excluded, and a relatively sufficient read margin of the OTP cell may be secured.

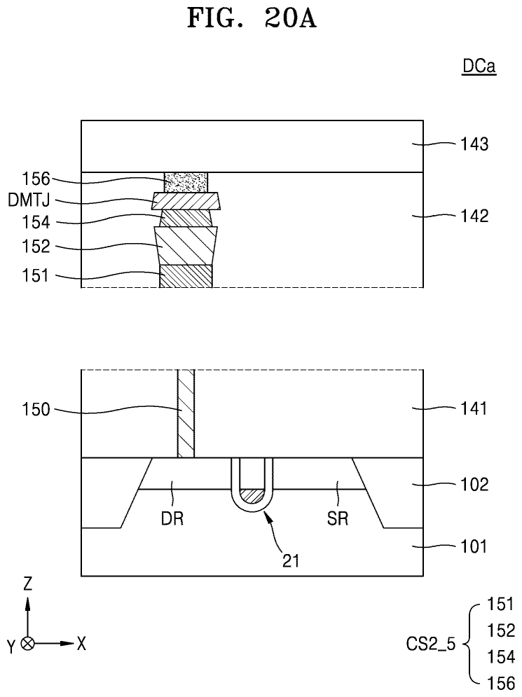

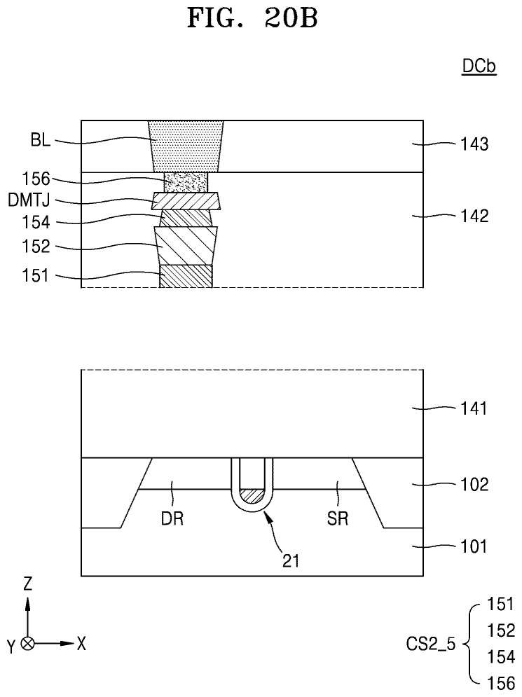

In the magnetic memory device of the inventive concept, as in the embodiment described above with reference to FIG. 8, when the first region 112a in which the normal memory cell array 112 is formed is adjacent to the second region 114a in which the OTP memory cell array 114 is formed, the distance dl (see FIG. 8) between the first MTJ structure MTJ1 and the second MTJ structure MTJ2 as described above with reference to FIG. 8 may be formed to be about 110 nanometers to 160 nanometers or about 130 nanometers to 140 nanometers to, reduce, minimize, or exclude the magnetic influence of the ferromagnetic lower conductive line 161, the ferromagnetic lower electrode contact 162, the ferromagnetic lower electrode 164, the ferromagnetic upper electrode 166, and/or the second bit line BL2′ on the first MTJ structure MTJ1. In another embodiment, a third region in which a dummy memory cell array is formed may be formed between the first region 112a in which the normal memory cell array 112 is formed and the second region 114a in which the OTP memory cell array 114 is formed. The structure including the dummy memory cell array is described in detail below with reference to FIGS. 19, 20A, and 20B.

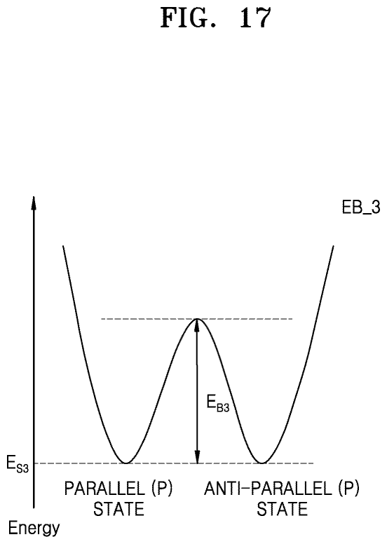

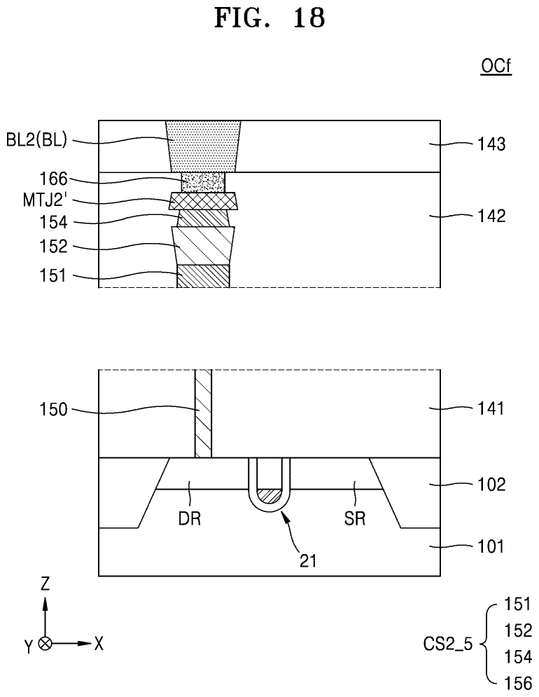

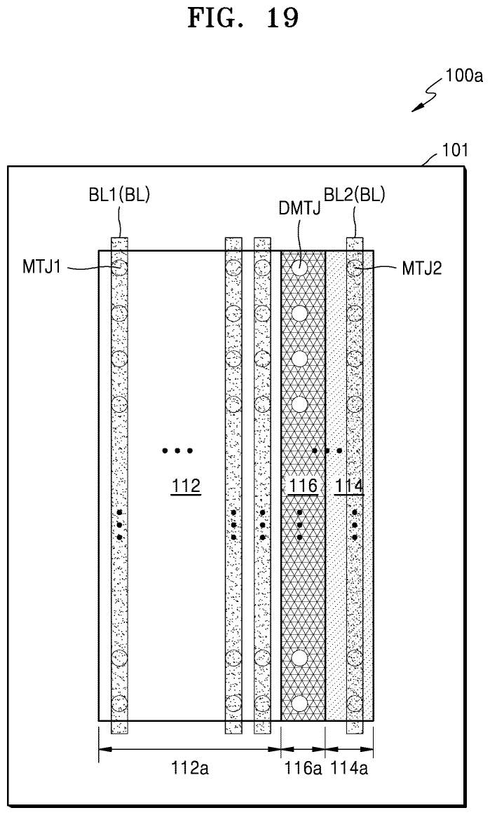

FIG. 17 is a graph schematically illustrating an energy band diagram EB_3 of an OTP memory cell according to an embodiment.

Referring to FIG. 17, the energies of the parallel (P) state and the anti-parallel (AP) state of the OTP memory cell according to an embodiment are each E_{S3}, and E_{S3} may be more stable in terms of energy, e.g., have greater energy stability, compared to the energy E_{S1} in each of the parallel (P) state and the anti-parallel (AP) state in the comparative example of FIG. 10A. In the OTP memory cell according to an embodiment, for a transition from the parallel (P) state to the anti-parallel (AP) state, the energy barrier of E_{B3} has to be overcome, and for a transition from the anti-parallel (AP) state to the parallel (P) state, the energy barrier of E_{B3} has to be overcome. Because the energy barrier of E_{B1} has to be overcome in the normal memory cell of FIG. 10A, it can be ascertained that, for the transition from the parallel (P) state to the anti-parallel (AP) state and for the transition from the anti-parallel (AP) state to the parallel (P) state, a relatively large energy barrier of E_{B3} has to be overcome. Accordingly, it may be assumed that the parallel (P) state and anti-parallel (AP) state of the OTP memory cell will be relatively stable in terms of energy.

By stabilizing the parallel (P) state and the anti-parallel (AP) state of the OTP memory cell in terms of energy, a resistance difference between the OTP memory cell in the parallel (P) state and the OTP memory cell in the anti-parallel (AP) state may be increased, and by reducing the likelihood of a transition between the parallel (P) state and the anti-parallel (AP) state due to an external environment, a relatively sufficient read operation margin may be secured. In order to stabilize the parallel (P) state and the anti-parallel (AP) state of the OTP memory cell in terms of energy, magnetic anisotropy of the MTJ may be strengthened. Hereinafter, as an example, a method of enhancing magnetic anisotropy is described.

FIG. 18 is a cross-sectional view illustrating an OTP memory cell structure OCf of a magnetic memory device according to an embodiment.

A second MTJ structure MTJ2′ of FIG. 18 may be configured to be substantially similar to the first MTJ structure MTJ1 of FIG. 11, so the differences from the first MTJ structure MTJ1 are described in detail below.

Referring to FIG. 18, the second MTJ structure MTJ2′ included in the OTP memory cell 30 (see FIG. 1) of the OTP memory cell array 114 (see FIG. 1) is shown. The second MTJ structure MTJ2′, similar to the first MTJ structure MTJ1, may include a pinned layer, a tunnel barrier layer, and a free layer. The second MTJ structure MTJ2′ may be an MTJ structure with relatively enhanced magnetic anisotropy compared to the first MTJ structure MTJ1.

In embodiments, the second MTJ structure MTJ2′ may have an oxidized free layer or may have a structure having a relatively more oxidized free layer compared to the first MTJ structure MTJ1 and the second MTJ structure MTJ2 described above. In other embodiments, the second MTJ structure MTJ2′ may have a structure further including an anti-ferromagnetic layer. For example, referring to FIGS. 5A and 5B, the second MTJ structure MTJ2′ may include the pinned layer 51, the tunnel barrier layer 52, the free layer 53, and the anti-ferromagnetic layer 54. The anti-ferromagnetic layer 54 may include at least one material selected from PtMn, IrMn, MnO, MnS, MnTe, MnF, FeCl, FeO, CoCl, CoO, NiCl, NiO, and/or Cr. When the anti-ferromagnetic layer is further included, local exchange interaction may occur. In addition, the second MTJ structure MTJ2′ may adopt an MTJ structure with relatively enhanced magnetic anisotropy using various methods.

In embodiments, the magnetic memory device of the inventive concept may include the second MTJ structure MTJ2′, the lower conductive line 151, the lower electrode contact 152, the lower electrode 154, the upper electrode 156, and the bit line BL. In other embodiments, the magnetic memory device of the inventive concept may include at least one of the second MTJ structure MTJ2′ and the ferromagnetic lower conductive line 161, the ferromagnetic lower electrode contact 162, the ferromagnetic lower electrode 164, the ferromagnetic upper electrode 166, and the second bit line BL2′.

FIG. 19 is a schematic plan view of a magnetic memory device 100a according to an embodiment. The magnetic memory device 100a is configured to be substantially similar to the magnetic memory device 100 of FIG. 8, so differences from the magnetic memory device 100 are described in detail below.

Referring to FIG. 19, the magnetic memory device 100a may include the substrate 101, and the substrate 101 may include the first region 112a in which the normal memory cell array 112 including the normal memory cells is located, the second region 114a in which the OTP memory cell array 114 including the OTP memory cells is located, and a third region 116a in which a dummy memory cell array 116 including a plurality of dummy memory cells is located. In embodiments, the third region 116a may be located between the first region 112a and the second region 114a.

A dummy MTJ structure DMTJ constituting the dummy memory cell may be disposed in the third region 116a. A plurality of dummy MTJ structures DMTJ may be arranged to be spaced apart from each other in the first horizontal direction (X-direction) and the second horizontal direction (the Y-direction).

Here, as described above, the normal memory cells of the normal memory cell array 112 may be programmed a plurality of times, while OTP memory cells of the OTP memory cell array 114 may be programmed only once. The dummy memory cells of the dummy memory cell array 116 may not be programmable. The dummy MTJ structure DMTJ constituting each dummy memory cell may not be connected to a bit line (not shown) and/or a source line (not shown) and may not operate as a variable resistance element.

FIG. 20A is a cross-sectional view illustrating a dummy memory cell structure DCa of a magnetic memory device according to an embodiment. The dummy memory cell structure DCa of FIG. 20A may be configured to be substantially similar to the normal memory cell structure NC, so the differences from the normal memory cell structure NC are described in detail below.

Referring to FIG. 20A, the dummy MTJ structure DMTJ included in the dummy memory cell structure DCa in the third region 116a (see FIG. 11) may be connected to the drain region DR of the selection transistor 21 formed below the dummy MTJ structure DMTJ through the contact 150 and may not be connected to the bit line (not shown) formed thereabove.

The drain region DR of the selection transistor 21 may be electrically connected to the lower conductive line 151 through the contact 150 passing through the first insulating layer 141 and may be electrically connected to the lower electrode contact 152 through the lower conductive line 151. The lower electrode 154 is formed on the lower electrode contact 152, and the dummy MTJ structure DMTJ is formed on the lower electrode 154. The upper electrode 156 is formed on the dummy MTJ structure DMTJ. In some embodiments, the lower electrode contact 152, the lower electrode 154, the dummy MTJ structure DMTJ, and the upper electrode 156 may be located within the second insulating layer 142.

Here, an upper surface of the upper electrode 156 may be at least partially covered with the third insulating layer 143. That is, the bit line (not shown) may not be electrically connected to the dummy MTJ structure DMTJ. Accordingly, the dummy device including the dummy MTJ structure DMTJ cannot operate as a memory element.

FIG. 20B is a cross-sectional view illustrating a dummy memory cell structure DCb of a magnetic memory device according to an embodiment. The dummy memory cell structure DCb of FIG. 20B may be configured to be substantially similar to the normal memory cell structure NC, so the differences from the normal memory cell structure NC are described in detail below.

Referring to FIG. 20B, the dummy MTJ structure DMTJ included in the dummy memory cell structure DCa in the third region 116a (see FIG. 11) may not be electrically connected to the drain region DR of the selection transistor 21 formed therebelow and may be electrically connected to the bit line BL formed thereabove through the upper electrode 156.

The lower electrode 154 is formed on the lower electrode contact 152, and the dummy MTJ structure DMTJ is formed on the lower electrode 154. The upper electrode 156 is formed on the dummy MTJ structure DMTJ, and the bit line BL is electrically connected to the dummy MTJ structure DMTJ through the upper electrode 156. In some embodiments, the lower electrode contact 152, the lower electrode 154, the dummy MTJ structure DMTJ, and the upper electrode 156 may be located within the second insulating layer 142. In addition, the bit line BL may be located within the third insulating layer 143.

Here, an upper surface of the drain region DR of the selection transistor 21 may be at least partially covered with the first insulating layer 141. That is, a contact (not shown) may not be electrically connected to the dummy MTJ structure DMTJ. In other words, a source line (not shown) may not be electrically connected to the dummy MTJ structure DMTJ. Therefore, a dummy memory element including the dummy MTJ structure DMTJ cannot operate as a memory element.

In embodiments, the magnetic memory device of FIGS. 20A and 20B may include a second conductive structure CS2_5, and the second conductive structure CS2_5 may include the lower conductive line 151, the lower electrode contact 152, the lower electrode 154, and the upper electrode 156. In other embodiments, the magnetic memory device of FIGS. 20A and 20B may include the ferromagnetic lower conductive line 161, the ferromagnetic lower electrode contact 162, the ferromagnetic lower electrode 164, and/or the ferromagnetic lower electrode contact 164 described above with reference to FIGS. 12 to 16.

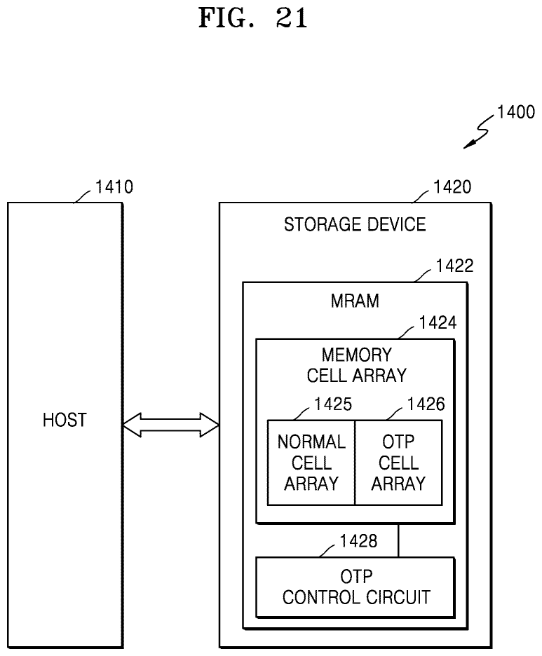

FIG. 21 is a block diagram illustrating an electronic device 1400 including a magnetic memory device according to an embodiment.

Referring to FIG. 21, the electronic device 1400 includes a host 1410 and a storage device 1420.

The host 1410 may include a user device, such as a personal computer, a portable computer, a tablet personal computer (PC), a smartphone, a digital camera, a camcorder, etc. The host 1410 stores data in or reads data from the storage device 1420 through an input/output request.

The host 1410 may be connected to the storage device 1420 through various interfaces, such as universal serial bus (USB), multimedia card (MMC), peripheral component interconnection (PCI), PCI-express (PCI-E), advanced technology attachment (ATA), serial-ATA, parallel-ATA, small computer small interface (SCSI), enhanced small disk interface (ESDI), and integrated drive electronics (IDE).

The storage device 1420 may be a data storage unit for performing a write operation or a read operation according to an input/output request from the host 1410 and may include a magnetic memory device (i.e., MRAM) 1422. The magnetic memory device 1422 includes a memory cell array 1424 and an OTP control circuit 1428, and the memory cell array 1424 includes a normal memory cell array 1425 and an OTP memory cell array 1426.

Normal memory cells including a first selection transistor and a first variable resistance element are arranged in the normal memory cell array 1425, and bit lines of the normal memory cells are provided to a sense amplifier. OTP memory cells including a second selection transistor and a short-circuited second variable resistance element are arranged in the OTP memory cell array 1426, and an OTP bit line of the OTP memory cell is provided to the sense amplifier.

The OTP control circuit 1428 generates a reference resistance in place of the short-circuited second variable resistance element of the OTP memory cell and provides the reference resistance to the OTP bit line. The sense amplifier improves a sensing margin of the normal memory cell by detecting and amplifying current flowing through the OTP bit line of the OTP memory cell to which the bit line of the normal memory cell and the reference resistance are connected.

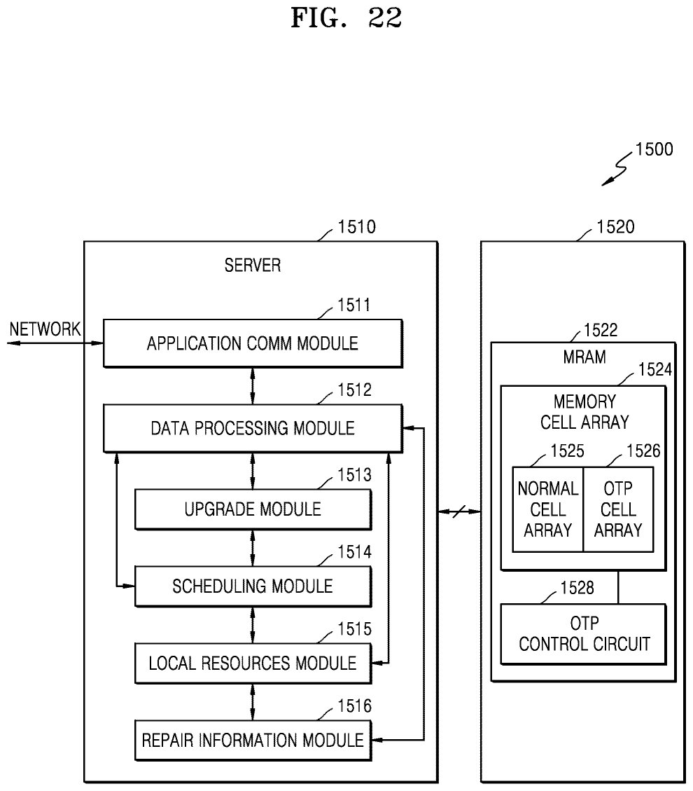

FIG. 22 is a block diagram illustrating a server system 1500 including a magnetic memory device according to an embodiment.

Referring to FIG. 22, the server system 1500 includes a server 1510 and at least one storage device 1520 that stores data used to operate the server 1510.

The server 1510 includes an application communication module 1511, a data processing module 1512, an upgrade module 1513, a scheduling module 1514, a local resource module 1515, and a repair information module 1516. The application communication module 1511 may be implemented to communicate with a computing system connected to the server 1510 via a network or cause the server 1510 and the storage device 1520 to communicate with each other. The application communication module 1511 transmits data or information provided through a user interface to the data processing module 1512.

The data processing module 1512 is linked to the local resource module 1515. The local resource module 1515 provides a list of repair shops/dealers/technical information based on data or information connected to the server 1510. The upgrade module 1513 interfaces with the data processing module 1512. The upgrade module 1513 upgrades firmware, reset code, a diagnostic system, or other information to an electronic product based on data or information transmitted from the storage device 1520.

The scheduling module 1514 allows a real-time option to a user based on data or information input to the server 1510. The repair information module 1516 interfaces with the data processing module 1512. The repair information module 1516 is used to provide repair-related information, for example, audio, video, or document files, to the user. The data processing module 1512 packages related information based on information transmitted from the storage device 1520. Such information is transmitted to storage device 1520 or displayed to the user. The storage device 1520 may include a magnetic memory device (or MRAM) 1522 as a data storage unit.

The magnetic memory device 1522 includes a memory cell array 1524 and an OTP control circuit 1528, and the memory cell array 1524 includes a normal memory cell array 1525 and an OTP memory cell array 1526.

Normal memory cells including a first selection transistor and a first variable resistance element are arranged in the normal memory cell array 1525, and bit lines of the normal memory cells are provided to a sense amplifier. OTP memory cells including a second selection transistor and a short-circuited second variable resistance element are arranged in the OTP memory cell array 1526, and an OTP bit line of the OTP memory cell is provided to the sense amplifier.

The OTP control circuit 1528 generates a reference resistance in place of the short-circuited second variable resistance element of the OTP memory cell and provides the reference resistance to the OTP bit line. The sense amplifier improves a sensing margin of the normal memory cell by detecting and amplifying current flowing through the OTP bit line of the OTP memory cell to which the bit line of the normal memory cell and the reference resistance are connected.

While the inventive concept has been particularly shown and described with reference to embodiments thereof, it will be understood that various changes in form and details may be made therein without departing from the spirit and scope of the following claims.

What is claimed is:

1. A magnetic memory device comprising:
a substrate including a first region and a second region adjacent to the first region;
a first magnetic tunnel junction (MTJ) structure in the first region;
a second MTJ structure in the second region;
a first bit line electrically connected to the first MTJ structure;
a second bit line electrically connected to the second MTJ structure;
a first conductive structure between the substrate and the first MTJ structure and between the first MTJ structure and the first bit line; and
a second conductive structure between the substrate and the second MTJ structure and between the second MTJ structure and the second bit line,
wherein the second bit line, the second conductive structure, or both of the second bit line and the second conductive structure include a ferromagnetic material,
wherein the first MTJ structure and the second MTJ structure each include a pinned layer, a tunnel barrier layer, and a free layer, and
wherein the tunnel barrier layer of the second MTJ structure is configured to break down and the second MTJ structure is configured to transition to an irreversible state in response to application of a breakdown voltage to the second MTJ structure.

2. The magnetic memory device of claim 1, wherein the first bit line and the first conductive structure include molybdenum (Mo), copper (Cu), tungsten (W), cobalt (Co), ruthenium (Ru), manganese (Mn), titanium (Ti), tantalum (Ta), aluminum (Al), combinations thereof, alloys thereof, or metal nitrides.

3. The magnetic memory device of claim 1, wherein the second bit line, the second conductive structure, or combinations thereof include at least one material selected from iron (Fe), cobalt (Co), nickel (Ni), gadolinium (Gd), dynamium diode (Dy), CoFeB, CoFe, NiFe, MnAs, MnBi, MnSb, CrO, MnOFeO, FeOFeO, NiOFeO, CuOFeO, MgOFeO, EuO, and YFeO.

4. The magnetic memory device of claim 1, wherein
the first MTJ structure and a first selection transistor electrically connected to the first MTJ structure constitute a normal memory cell, which is programmable a plurality of times, and
the second MTJ structure and a second selection transistor electrically connected to the second MTJ structure constitute a one-time programmable memory cell, which is programmable only once.

5. The magnetic memory device of claim 1, wherein an anti-parallel state of the second MTJ structure is in a lower energy state than an anti-parallel state of the first MTJ structure.

6. The magnetic memory device of claim 1, wherein an energy barrier from a parallel state to the anti-parallel state of the second MTJ structure is smaller in height than an energy barrier from the parallel state to the anti-parallel state of the first MTJ structure.

7. The magnetic memory device of claim 1, wherein an energy barrier from the parallel state to the anti-parallel state of the second MTJ structure is smaller in height than an energy barrier from the anti-parallel state to the parallel state.

8. The magnetic memory device of claim 1, wherein
a magnetic anisotropy of the second MTJ structure is greater than a magnetic anisotropy of the first MTJ structure, and
the free layer of the second MTJ structure is oxidized.

9. The magnetic memory device of claim 1, wherein
a magnetic anisotropy of the second MTJ structure is greater than a magnetic anisotropy of the first MTJ structure, and
the second MTJ structure further includes an antiferromagnetic layer on the free layer.

10. The magnetic memory device of claim 9, wherein the anti-ferromagnetic layer of the second MTJ structure includes at least one material selected from PtMn, IrMn, MnO, MnS, MnTe, MnF, FeCl, FeO, CoCl, CoO, NiCl, NiO, and Cr.

11. The magnetic memory device of claim 1, wherein
the second conductive structure includes:
a lower electrode and an upper electrode electrically connected to the second MTJ structure and spaced apart from each other with the second MTJ structure therebetween;
a lower electrode contact electrically connected to the second MTJ structure through the lower electrode; and
a lower conductive line electrically connected to the lower electrode contact,
wherein at least one of the lower electrode, the upper electrode, the lower electrode contact, and the lower conductive line includes the ferromagnetic material.

12. A magnetic memory device comprising:
a substrate including a first region and a second region adjacent to the first region;
a first magnetic tunnel junction (MTJ) in the first region;
a second MTJ structure in the second region; and
a bit line and a selection transistor electrically connected to the first MTJ structure and the second MTJ structure, respectively,
wherein the first MTJ structure and the second MTJ structure each include a pinned layer, a tunnel barrier layer, and a free layer,
wherein an anti-parallel state of the second MTJ structure has greater energy stability than an anti-parallel state of the first MTJ structure,
wherein a second energy barrier from the anti-parallel state to a parallel state of the second MTJ structure is larger in height than a first energy barrier from the anti-parallel state to a parallel state of the first MTJ structure, and
wherein the tunnel barrier layer of the second MTJ structure is configured to break down and the second MTJ structure is configured to transition to an irreversible state in response to application of a breakdown voltage to the second MTJ structure.

13. The magnetic memory device of claim 12, wherein the parallel state of the second MTJ structure has less energy stability than the parallel state of the first MTJ structure.

14. The magnetic memory device of claim 12, wherein the parallel state of the second MTJ structure has greater energy stability than the parallel state of the first MTJ structure.

15. The magnetic memory device of claim 12, further comprising:
a dummy MTJ structure,
wherein the dummy MTJ structure is in a third region between the first region and the second region.

16. The magnetic memory device of claim 15, wherein the dummy MTJ structure is electrically disconnected from the bit line.

17. The magnetic memory device of claim 15, wherein the dummy MTJ structure is electrically disconnected from the selection transistor.

18. A magnetic memory device comprising:
a substrate including a first region and a second region adjacent to the first region;
a plurality of first memory elements constituting a normal memory cell in the first region;
a plurality of second memory elements constituting one-time programmable (OTP) memory cells in the second region;
a first bit line and a first selection transistor electrically connected to the plurality of first memory elements; and
a second bit line and a second selection transistor electrically connected to the plurality of second memory elements,
wherein the plurality of first memory elements and the plurality of second memory elements each include:
an MTJ structure including a pinned layer, a tunnel barrier layer, and a free layer, which are sequentially stacked;
a first conductive structure electrically connecting the first bit line to the MTJ structure and the MTJ structure to the first selection transistor in the first region; and
a second conductive structure electrically connecting the second bit line to the MTJ structure and the MTJ structure to the second selection transistor in the second region,
wherein the first conductive structure and the second conductive structure each include:
an upper electrode in contact with an upper surface of the MTJ structure;
a lower electrode in contact with a lower surface of the MTJ structure;
a lower electrode contact spaced apart from the MTJ structure with the lower electrode therebetween; and
a lower conductive line electrically connected to the lower electrode contact,
wherein the first conductive structure and the first bit line include a diamagnetic material or a paramagnetic material,
wherein the lower conductive line, the lower electrode contact, the lower electrode, the upper electrode, the second bit line, or combinations thereof constituting the second conductive structure include a ferromagnetic material, and
wherein the tunnel barrier layer of the MTJ structure is configured to break down and the MTJ structure is configured to transition to an irreversible state in response to application of a breakdown voltage to the MTJ structure and some of the plurality of second memory elements.

19. The magnetic memory device of claim 18, wherein
the MTJ structure includes:
a first MTJ structure electrically connected to the first conductive structure; and
a second MTJ structure electrically connected to the second conductive structure,
wherein an anti-parallel state of the second MTJ structure has greater energy stability than an anti-parallel state of the first MTJ structure, and
a second energy barrier from a parallel state to the anti-parallel state of the second MTJ structure is smaller in height than a first energy barrier from a parallel state to the anti-parallel state of the first MTJ structure.

20. The magnetic memory device of claim 18, wherein
some of the plurality of second memory elements are active elements,
the remaining second memory elements are dummy elements,
the active elements are in the second region, and
the dummy elements are in a third region between the first region and the second region.
